(19) United States
(12) Patent Application Publication
(10) Pub. No.: US 2026/0259252 A1
(43) Pub. Date: Sep. 3, 2026

(54) SYSTEM FOR POSITIONING ANTENNA UNDER TEST (AUT) WITH RESPECT TO OFFSET FEED ANTENNAS

(71) Applicant: Keysight Technologies, Inc., Santa Rosa, CA (US)

(72) Inventors: Abhinav Mahadevan, Santa Rosa, CA (US); Curt Kimble, Rohnert Park, CA (US)

(21) Appl. No.: 18/719,872

(22) PCT Filed: Oct. 24, 2022
(86) PCT No.: PCT/US2022/047577

§ 371 Date: Jun. 14, 2024

Related U.S. Application Data
(60) Provisional application No. 63/293,516, filed on Dec. 23, 2021.

(51) Int. Cl. G01R 29/10; G01R 29/08

(52) U.S. Cl. CPC G01R 29/105; G01R 29/0878

(57) ABSTRACT

A system is provided for measuring far-field characteristics of an AUT. The system includes an AUT positioner for positioning the AUT on a transverse axis; a curved reflector defining a reference focal plane corresponding to a focal point of the curved reflector at a reference position on the transverse axis of the AUT positioner; and a measurement array including feed antennas configured to communicate RF signals with the AUT via the curved reflector. A selected feed antenna is offset in a transverse direction from a reference line connecting the focal point and the reference position on the transverse axis, such that an offset focal plane corresponding to the selected feed antenna is angularly offset from the reference focal plane. The AUT positioner positions the AUT at an offset location, at which the AUT has a planar phase front parallel to the offset focal plane of the selected feed antenna.

### CROSS-REFERENCE TO RELATED APPLICATIONS

The present application is the U.S. National Stage Application under 35 U.S.C. § 371 of, and claims priority under 35 U.S.C. § 121 from, International Patent Application No. PCT/US2022/47577, filed on Oct. 24, 2022, and published as WO/2023121758 on Jun. 29, 2023, which claims priority under 35 U.S.C. § 119(e) to U.S. Provisional Application No. 63/293,516 filed on Dec. 23, 2021. The entire disclosures of International Patent Application No. PCT/US22/47577 and U.S. Provisional Application No. 63/293,516 are specifically incorporated herein by reference in their entireties.

### BACKGROUND

Antenna array test and calibration solutions are used to characterize antennas under test (AUTs), including antenna arrays, which may be integrated in corresponding devices under test (DUTs). Conventional solutions for test and calibration depend primarily on a vector network analyzer, which requires the DUT, including the AUT, to have radio frequency (RF) connectors, such as coaxial connectors, in order to perform the test and calibration. However, with the evolution of wireless communication technologies, AUTs with direct connections to (i.e., integrated with) RF transceivers of DUTs, and having no RF connectors, are becoming increasingly common. Overall performance of such an AUT presently must be tested “over-the-air,” since there is no place to connect a coaxial cable from the DUT and/or the AUT to the test equipment. In fact, due to integration, overall DUT performance must now be tested as a function of the AUT configuration. For instance, when a signal comprises multiple beams, the DUT performance must be characterized over a range of beam angles and/or widths.

Antenna characterization processes typically take place at an outdoor test range or in an anechoic chamber test range. The outdoor test ranges are used for antennas having a very long far-field (e.g., greater than 5 m), rendering use of an indoor test range or anechoic chamber impractical. Anechoic test ranges are shielded chambers with walls covered in absorbing material that minimizes internal reflections, typically by several tens of decibels.

There are a number of basic conventional techniques for antenna characterization using an anechoic chamber. First, for example, there is a simple-far-field measurement technique, which is appropriate when the antenna's far-field occurs at a sufficiently short distance that it can be measured in a chamber of practical size, e.g., less than a couple meters on the longest side. Second, there is the near-field measurement technique, according to which near-field measurements are mathematically transformed to the far-field. This type of measurement involves a raster scan over a plane in front of an AUT, or a cylinder or spherical surface around an AUT, and then a Fourier transform of corresponding measurements to calculate the far-field pattern of the antenna. Third, there is a compact anechoic test range (CATR) technique, according to which an approximately uniform source (a single probe antenna) illuminates a curved reflector (mirror) with a radiated signal where the resulting reflection provides a nearly perfectly collimated beam. In this way, the AUT with a long far-field distance can be positioned in the collimated beam, and its antenna pattern determined as the received power changes as a function of rotation angle (elevation and azimuth). The collimated reflection from the curved reflector allows the AUT to be characterized in the far-field in a more compact chamber than would otherwise be possible without the curved mirror.

Conventional solutions for over-the-air testing are aimed primarily at measurements by a single feed (probe) antenna, such as a single broadband feed horn. Use of a single broadband feed antenna will change and often times reduce the size of the test zone, although the user may have to replace the focal feed antenna to match the AUT's frequency range for a more consistent performance. Another option is to physically move the feed antennas in and out of the focus of the reflector. This causes measurement uncertainty when measuring the phase and amplitude of radio frequency (RF) signals of the AUT, and the changes are unpredictable when the alignment of the feed horn of the reflector is not perfect. Such changes are difficult to account for in the measurement process, thus leading to either a very expensive solution or a system with higher measurement uncertainty. These difficulties are more pronounced as the frequencies of the RF signals are scaled up.

What is needed is an inexpensive and efficient way to measure far-field characteristics of one or more AUTs at different frequencies using a single feed (probe) antenna of multiple available feed antennas offset from one another for each of the different frequencies, without having to reconfigure the test range.

### BRIEF DESCRIPTION OF THE DRAWINGS

The illustrative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements throughout the drawings and written description.

FIG. 1 is a simplified block diagram of a system for measuring at least one far-field characteristic of an AUT, according to a representative embodiment.

FIG. 2 is flow diagram of a method system for measuring at least one far-field characteristic of an AUT, according to a representative embodiment.

### DETAILED DESCRIPTION

In the following detailed description, for purposes of explanation and not limitation, example embodiments disclosing specific details are set forth in order to provide a thorough understanding of the present teachings. However, it will be apparent to one of ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical, scientific, or ordinary meanings of the defined terms as commonly understood and accepted in the relevant context.

The terms “a”, “an” and “the” include both singular and plural referents, unless the context clearly dictates otherwise. Thus, for example, “a device” includes one device and plural devices. The terms “substantial” or “substantially” mean to within acceptable limits or degree to one of ordinary skill in the art. The term “approximately” means to within an acceptable limit or amount to one of ordinary skill in the art. Relative terms, such as “above,” “below,” “top,” “bottom,” “upper” and “lower” may be used to describe the various elements” relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be below that element. Where a first device is said to be connected or coupled to a second device, this encompasses examples where one or more intermediate devices may be employed to connect the two devices to each other. In contrast, where a first device is said to be directly connected or directly coupled to a second device, this encompasses examples where the two devices are connected together without any intervening devices other than electrical connectors (e.g., wires, bonding materials, etc.).

Generally, according to various embodiments, a user does not have to touch the feed area of a Compact Antenna Test Range (CATR) for measuring far-field characteristics of one or more AUTs at different frequencies. The alignment of the entire CATR structure depends on the relationship between the feed antenna transmitting and receiving RF signals to and from the AUTs and the curved reflector, discussed below. By eliminating interference in this relationship, the possibilities of mishaps that would significantly affect performance of the CATR are reduced. Further, the embodiments drastically reduce test times and also improve accuracy for users who are testing broadband antennas, since there is minimal mechanical movement, e.g., of the AUTs, and no reconfiguring of the feed antennas.

In a representative embodiment, a system is provided for measuring at least one far-field characteristic of an AUT. The system includes an AUT positioner configured to position the AUT on a transverse axis of the AUT positioner; a curved reflector defining a reference focal plane corresponding to a focal point of the curved reflector at a reference position on the transverse axis of the AUT positioner; and a measurement array including multiple feed antennas configured to transmit RF signals to the AUT and/or receive RF signals from the AUT reflected by the curved reflector. A selected feed antenna of the multiple feed antennas is offset in a transverse direction from a reference line connecting the focal point of the curved reflector and the reference position on the transverse axis of the AUT positioner, such that an offset focal plane corresponding to the selected feed antenna is angularly offset from the reference focal plane. The AUT positioner is configured to position the AUT at a laterally offset location and at an offset angle for receiving RF signals from the selected feed antenna and/or transmitting RF signals to the selected feed antenna, where when positioned at the offset location at the offset angle, the AUT is positioned in center of the quiet zone and has a planar phase front parallel to the offset focal plane of the selected feed antenna.

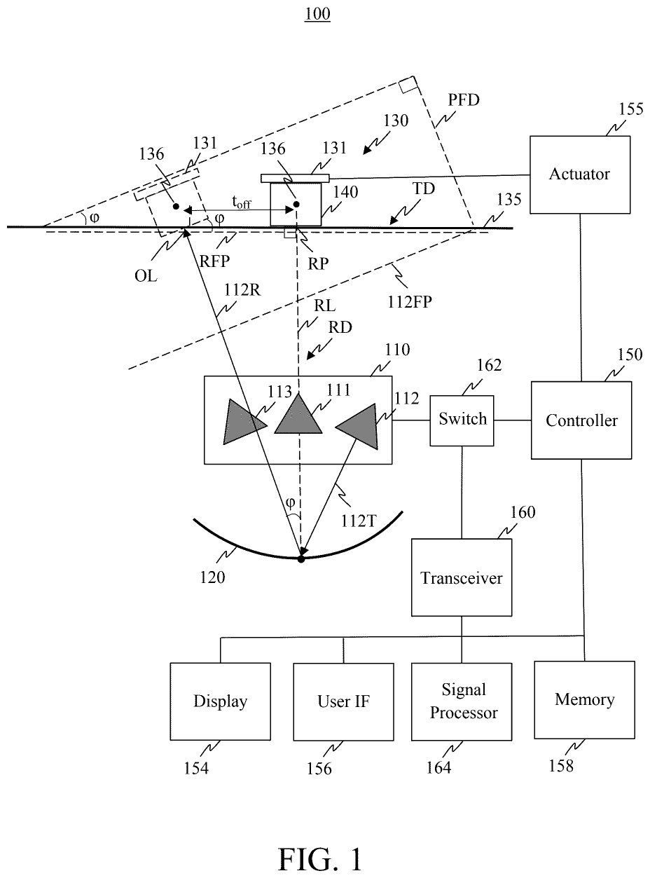

FIG. 1 is a simplified block diagram of a system for measuring at least one far-field characteristic of an AUT, according to a representative embodiment.

Referring to FIG. 1, system 100 is a multi-probe CATR that includes a measurement antenna array 110, a curved (e.g., parabolic) reflector 120, and an AUT positioner 130. The AUT positioner 130 is configured to move the AUT 140 linearly along a transverse axis 135 and rotationally around an azimuth axis 136 (shown perpendicular to the plane of the drawing) of the AUT 140 when mounted to a moveable platform 131 of the AUT positioner 130 for testing. For purposes of illustration, it may be assumed that the azimuth axis 136 of the AUT 140 substantially aligns with an azimuth axis of the movable platform 131. The testing includes transmitting RF signals to the AUT 140 and/or receiving RF signals from the AUT 140 via the measurement antenna array 110. The AUT 140 is movable to different positions along the transverse axis 135 and to different angles around the azimuth axis 136 during the testing, depending on which of the feed antennas of the measurement antenna array 110 is being used, as discussed below. The curved reflector 120 is configured to reflect the RF signals transmitted and/or received by the measurement antenna array 110, thereby effectively increasing the distance between the measurement antenna array 110 and AUT 140 to enable far-field measurements. In an embodiment, the measurement antenna array 110, the curved reflector 120, the AUT positioner 130, and the AUT 140 are located within an anechoic chamber, which includes electromagnetic wave absorbing material on the interior walls. The electromagnetic wave absorbing material minimizes reflections from the internal walls, e.g., by several tens of decibels, reducing interference.

The system 100 is configured to measure at least one far-field characteristic of the AUT 140, which may be integrated with a DUT. Examples of far-field characteristics of the DUT include an error-vector-magnitude (EVM) and adjacent channel leakage ratios (ACLRs), and examples of far-field characteristics of the AUT 140 include antenna profile and effective isotropic radiated power (EIRP). The AUT 140 may be implemented as a single antenna or multiple antennas in an antenna array, e.g., arranged in a matrix-type format. When the AUT 140 is integrated with a DUT, the AUT 140 cannot be tested in isolation, assuming there are no RF connections to the AUT 140. That is, it is not possible to simply test the antenna profile of the AUT 140, and then separately test functionality of the transmitter chain and/or receiver chain of the DUT. Characterization of the AUT 140 and the DUT may therefore be performed at the same time.

The curved reflector 120 includes a focal point FP, which aligns perpendicularly with a reference point RP on the transverse axis 135 of the AUT positioner 130, indicated by reference line RL. The measurement antenna array 110 includes multiple feed (probe) antennas, indicated in FIG. 1 by representative first feed antenna 111, second feed antenna 112 and third feed antenna 113, which may be probe antennas or horn antennas, for example. In the depicted embodiment, the first feed antenna 111 is located in a center position on the reference line RL, the second feed antenna 112 is offset in the transverse direction from the reference line RL to the right and the third feed antenna 113 is offset in the transverse direction from the reference line RL to the left, e.g., an equal distance as the second feed antenna 112. Thus, the second feed antenna 112 is offset to the right of the first feed antenna 111, and the third feed antenna 113 is offset to the left of the first feed antenna 111. The reference point RP corresponds to a location of the AUT 140 on the transverse axis 135 where the AUT would be ideally positioned in a quiet zone (discussed below) for receiving and transmitting RF signals with the first feed antenna 111.

The first feed antenna 111, the second feed antenna 112 and the third feed antenna 113 may be configured to operate at different frequencies from one another, respectively. This enables the AUT 140 to be tested at different frequencies without having to change out feed antennas, and/or enables different types of AUTs to be tested by the system 100 without having to change out feed antennas. Of course, the number and locations of the feed antennas may vary to provide unique benefits for any particular situation or to meet application specific design requirements of various implementations, without departing from the scope of the present teachings.

Each of the first feed antenna 111, the second feed antenna 112 and the third feed antenna 113 is positioned to transmit and receive RF signals reflected at the focal point FP of the curved reflector 120. Accordingly, the first feed antenna 111 transmits and receives RF signals in a direction indicated by the reference line RL, which corresponds to the center of a reflected beam from the first feed antenna 111 and the curved reflector 120. This results in a reference focal plane RFP that is perpendicular to the reference line RL and thus is substantially parallel to the transverse axis 135 of the AUT positioner 130. Notably, the reference line RL and the reference focal plane RFP are functions of the shape of the curved reflector 120, including the location of the focal point FP, and therefore remain the same regardless of whether there is a feed antenna located at the center position.

AUT 140 is shown positioned at the center of a collimated beam coming from the curved reflector 120 with respect to the reference focal plane RFP, where the collimated beam region extends from the reference focal plane RFP to a parallel plane where the collimated beam diverges from the AUT 140. The collimated beam region may also be referred to as the quiet zone, which is a substantially cylindrical region where phase and amplitude variations of the RF signals communicated to and from the AUT 140 are minimized.

The second feed antenna 112 and the third feed antenna 113, being offset from the reference line RL, transmit and receive RF signals in directions angularly offset from the reference line RL, resulting in corresponding offset focal planes that are tilted (skewed) relative to the reference focal plane RFP by an offset angle. For example, referring to the second feed antenna 112 for purposes of explanation, a transmitted RF signal indicated by arrow 112T is reflected at the focal point FP of the curved reflector 120 toward the AUT positioner 130 indicated by arrow 112R. The arrow 112R corresponds to the center of the reflected beam from the second feed antenna 112 and the curved reflector 120. The resulting offset focal plane 112FP is perpendicular to the arrow 112R, and is tilted relative to the reference focal plane RFP by an offset angle φ. Accordingly, when the AUT 140 is located in a first position at the reference point RP on the transverse axis 135, it is not centered in a beam width of the RF signal transmitted by the second feed antenna 112 in the direction of the arrow 112R, and is not angled toward (parallel to) the offset focal plane 112FP.

Therefore, the AUT 140 should be located at in a second position at offset location OL on the transverse axis 135 (where the AUT 140 is indicated by dashed lines), and rotated on the azimuth axis 136 by the offset angle φ, in order to optimize reception of the RF signal transmitted by the second feed antenna 112. That is, by moving the AUT 140 to the new offset location OL, the AUT 140 is assured to be in the center of the quiet zone associated with the second feed antenna 112, or in the location where the collimated beam is centered. Also, by rotating the AUT 140 by the offset angle φ when positioned at the offset location OL, the AUT 140 has a planar phase front that is parallel to the offset focal plane 112FP of the second feed antenna 112. So, by controlling linear movement of the AUT 140 along the transverse axis 135, and rotational movement the AUT 140 in the azimuth direction on the azimuth axis 136, the AUT 140 is placed within the center of the quiet zone, and is rotationally aligned with the offset focal plane 112FP coming in from the offset second feed antenna 112.

In order to correctly position the AUT 140 at the correct offset location OL, controller 150 of the system 100 determines a transverse offset t_{off} between the reference point RP on the transverse axis 135 of the AUT positioner 130 (corresponding to the first position P1 of the AUT 140) and the desired offset location OL (offset location) of the AUT 140, and determines the offset angle φ corresponding to the angle of rotation of the AUT 140 on the azimuth axis 136 at the offset location OL. The controller 150 is then able to control linear and rotational movement of the moveable platform 131 carrying the AUT 140 via a linear actuator 155 and a rotational actuator (not shown). The linear actuator 155 may move the moveable platform 131 along the transverse axis 135 over a distance equal to the transverse offset t_{off}. The linear actuator 155 may be an electro-mechanical (e.g., screw-type), hydraulic or pneumatic actuator, for example, although any type of compatible linear actuator may be incorporated without departing from the scope of the present teachings. The rotational actuator may be located at that moveable platform 131, and may rotate the moveable platform 131 to an angle equal to the offset angle φ. The rotational actuator also may be an electro-mechanical, hydraulic or pneumatic actuator, for example, although any type of compatible rotational actuator may be incorporated without departing from the scope of the present teachings. The linear actuator 155 and/or the rotational actuator may include steppers or servo motors controllable by the controller 150 for appropriate positioning. Alternatively, the moveable platform 131 may be positioned along the transverse axis 135 and/or rotated manually by hand or via user interface (IF) 156 based on the offset location OL and the offset angle φ determined by the controller 150 and displayed on a display 154.

The transverse offset t_{off} is determined based on the offset angle φ and the reflector distance (RD) between the focal point FP of the curved reflector 120 and the reference point RP on the transverse axis 135, which is the length of the reference line RL in the depicted example. In particular, as shown in FIG. 1, a portion of the transverse axis 135 is the hypotenuse of a right triangle that includes the offset angle φ, where the opposite side of the right triangle from the offset angle φ may be referred to as phase front distance (PFD) and the hypotenuse may be referred to as transverse distance (TD).

In order to determine the offset angle φ, the transverse distance (TD) is initially estimated, for example, as the distance over which the moveable platform 131 may move along the transverse axis 135. The phase front distance (PFD) is then determined based on phase of the RF signal measured at the beginning and the end of the movement of the AUT 140 over the transverse distance (TD) along the transverse axis 135, multiplied by the wavelength of the RF signal in the test and divided by 360, as indicated by Equation (1):

$$PFD = \frac{ABS ( phase start - phase end ) * λ}{360} \qquad Equation ( l )$$

Referring to Equation (1), “phase start” is the phase of the RF signal measured at the beginning of the movement of the AUT 140 (at the reference point RP), “phase end” is the phase of the RF signal measured at the end of the movement of the AUT 140 (at an arbitrary point past the offset location OL), and “ABS” indicates absolute value. The phase measurements may be made by either the selected feed antenna (second feed antenna 112 in the present example) or the AUT due to the reciprocal nature of the curved reflector 120. The phase measurements may be made in real time, during the transmission of the RF signal, although calculation of the offset angle φ and the transverse offset t_{off} may be done once the phase measurements are completed.

The offset angle φ may be then be determined based on the phase front distance (PFD) and the transverse distance (TD), according to Equation (2):

$$φ = arcsin ( \frac{PFD}{TD} ) \qquad Equation ( 2 )$$

The angle between the arrow 112R, corresponding to the center of the reflected beam from the second feed antenna 112 and the curved reflector 120, and the reference line RL is also equal to the offset angle φ, forming another right triangle in which the opposite side of the right triangle from the offset angle φ is equal to the transverse offset t_{off}. So, the transverse offset t_{off} may be determined according to Equation (3), where the reflector distance is the length of the reference line RL, as mentioned above:

t_{offset}=tan(φ)*reflector distance Equation (3)

By moving the moveable platform 131 of the AUT positioner 130 linearly along the transverse axis 135 over the transverse offset t_{off} to the offset location OL, the AUT 140 is in the center of the quiet zone of the second feed antenna 112. By rotating the moveable platform of the AUT positioner 130 around the azimuth axis 136, the AUT 140 is aligned with the appropriate offset focal plane of the second feed antenna 112, and is guaranteed to have a planar phase front perpendicular to the center of the main beam of the reflected RF signal indicated by arrow 112R, thereby reducing or eliminating systemic errors otherwise caused by the test configuration. Accordingly, the system 100 is able to utilize any of the first, second and third feed antennas 111, 112 and 113 in the measurement antenna array 110 as the “focal” feed antenna by repositioning the AUT 140 as discussed above to be in the appropriate quiet zone and corresponding offset focal plane.

The controller 150 may calculate the offset angle φ and the transverse offset t_{off} during the testing procedure. Alternatively, the different offset angles φ and transverse offsets t_{off} corresponding to different offset positions of the feed antennas (e.g., second and third feed antennas 112 and 113) may be determined ahead of time and stored, e.g., as a look-up table, in the memory 158. In this case, the controller 150 simply retrieves the offset angle φ and the transverse t_{off} from the memory 158. Either way, the controller 150 then controls movement of the AUT positioner 130 to the appropriate angle with respect to the azimuth axis 136 according to the offset angle φ and to the appropriate location on the transverse axis 135 according to the transverse offset t_{off}.

In the depicted embodiment, for purposes of illustration, the first feed antenna 111, the second feed antenna 112 and the third feed antenna 113 of the measurement antenna array 110 are selectively connected to representative transceiver 160 through operation of a representative switch 162 under control of the controller 150. The transceiver 160 is therefore able to receive RF signals transmitted from the AUT 140 and to transmit RF signals to the AUT 140 via the first feed antenna 111, the second feed antenna 112 and the third feed antenna 113, respectively. Although the depicted embodiment shows one transceiver (160) and one switch (162), it is understood that additional transceivers and/or switches may be incorporated without departing from the scope of the present teachings. For example, each of the feed antennas of the measurement antenna array 110 may have a corresponding, dedicated switch for selectively connecting that feed antenna. Or, each of the feed antennas of the measurement antenna array 110 may have a corresponding, dedicated transceiver, in which case there may be no need for switches.

The transceiver 160 and the switch 162 may be outside the anechoic chamber, mentioned above, and configured to communicate with the measurement antenna array 110 by a physical connection (as shown), such as a cable, passing through wall(s) of the anechoic chamber, or to communicate wirelessly. However, it is understood that one or both of the transceiver 160 and the switch 162 may be located inside the anechoic chamber, without departing from the scope of the present teachings.

In the depicted embodiment, the system 100 further includes a signal processor 164 coupled to the transceiver 160 and configured to perform the measurements of the AUT 140 and/or the integrated DUT characteristics. Examples of the signal processor 164 may include a signal generator, a signal analyzer, a communication transceiver, or various combinations thereof. The system 100 further includes display 154, user IF 156 and memory 158.

The display 154 is configured to display various information determined by the controller 150, such as position and location information (e.g., offset location OL) with regard to positioning the AUT 140 via the AUT positioner 130, as well as feed antenna selection information. The display 154 may also be configured to display RF signals transmitted and received by the measurement antenna array 110, as well as data indicating measurement of the at least one far-field characteristic of the AUT 140 and/or the he integrated DUT characteristics. The display 154 may be a monitor such as a computer monitor, a television, a liquid crystal display (LCD), an organic light emitting diode (OLED), a flat panel display, a solid-state display, or a cathode ray tube (CRT) display, or an electronic whiteboard, for example. The display 154 may also provide a graphical user interface (GUI) for displaying and receiving information to and from the user operating in conjunction with the user IF 156.

The user IF 156 is configured to enable a user to interface with the system 100, via the controller 150 and/or the signal processor 164, for example. The user IF 156 may be integrated with the display 154 as a GUI, discussed above. For example, the user IF 156 may be used to select which of the first, second and third feed antennas 111, 112 and 113 to activate for transmitting and receiving RF signals. The user IF 156 may also be used to manually control movement of the moveable platform 131 based on the offset location OL determined by the controller 150 and displayed on a display 154. The user IF 156 may include a keyboard, a mouse, a touch pad and/or a touch-sensitive display, for example, although any other compatible means of providing input may be incorporated without departing from the scope of the present teachings.

Each of the controller 150 and the signal processor 164 comprise one or more processing units, which may be implemented by a one or more computer processors, application specific integrated circuits (ASICs), field-programmable gate arrays (FPGAs), digital signal processors (DSPs), graphics processor units (GPUs), central processing units (CPUs), or combinations thereof, using software, firmware, hard-wired logic circuits, or combinations thereof. As such, the term “processing unit” encompasses an electronic component able to execute a program or machine executable instructions, may be interpreted to include more than one processor or processing core, as in a multi-core processor and/or parallel processors. The processing units may also incorporate a collection of processors within a single computer system or distributed among multiple computer systems, such as in a cloud-based or other multi-site application. Programs have software instructions performed by one or multiple processors that may be within the same computing device or which may be distributed across multiple computing devices.

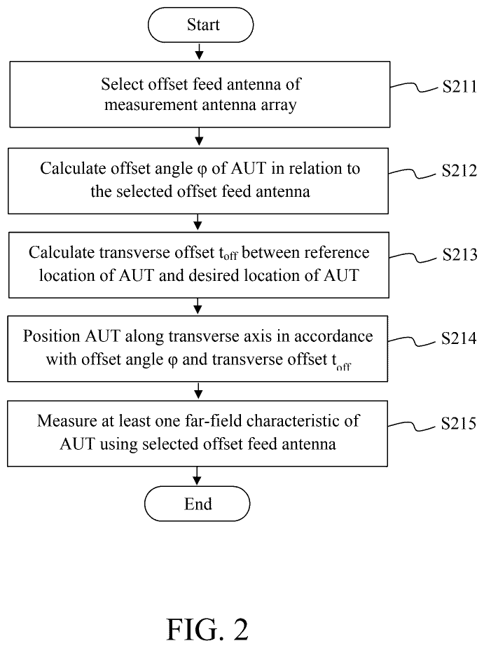

The memory 158 is configured to store at least a portion of the measurement results, e.g., provided by the signal processor 164, as well as instructions executable by the controller 150 for controlling operation of the AUT positioner 130 and for selecting the first, second and third feed antennas 111, 112 and 113 in the measurement antenna array 110. The memory 158 may include a main memory and/or a static memory, where such memories may communicate with each other, and with the controller 150 and the signal processor 164 via one or more buses. The memory 158 stores instructions used to implement some or all aspects of methods and processes described herein, including the functions and methods described above with reference to FIG. 2, for example. The memory 158 may be implemented by any number, type and combination of random access memory (RAM) and read-only memory (ROM), for example, and may store various types of information, such as software algorithms, data based models including ANN and other neural network based models, and computer programs, all of which are executable by the controller 150 and/or the signal processor 164. The various types of ROM and RAM may include any number, type and combination of computer readable storage media, such as a disk drive, flash memory, an electrically programmable read-only memory (EPROM), an electrically erasable and programmable read only memory (EEPROM), registers, a hard disk, a removable disk, tape, compact disk read only memory (CD-ROM), digital versatile disk (DVD), floppy disk, blu-ray disk, a universal serial bus (USB) drive, or any other form of computer readable storage medium known in the art. The memory 158 is tangible, and is non-transitory during the time software instructions are stored therein. Although shown as a single memory, it is understood that the memory 158 may be implemented by any number of memories and/or databases, without departing from the scope of the present teachings.

In an embodiment, the first, second and third feed antennas 111, 112 and 113 may include detectors, such as power sensing diodes. The power sensing diodes may be configured to perform the substantially simultaneous measurements of the AUT 140 characteristics and/or the integrated DUT characteristics, for example, measurements of the antenna profile, which is basically power measured as a function of angle. In various embodiments, the measurements may be sent to the signal processor 164 and/or the memory 158.

FIG. 2 is flow diagram of a method for measuring at least one far-field characteristic of an AUT, according to a representative embodiment. The method may be implemented by the system 100, discussed above, under control of the controller 150 executing instructions stored as the various software modules in the memory 158, for example. That is, the system includes a measurement antenna array with one or more offset feed antennas, a curved reflector with a focal point for reflecting RF signals to and from the offset feed antennas, and an AUT positioner for moving an AUT linearly along a traverse axis to position the AUT in the appropriate offset focal plane of the offset feed antennas, and rotationally around an azimuth axis to angle the AUT to be parallel to the appropriate offset focal plane.

Referring to FIG. 2, a feed antenna of a measurement antenna array is selected in block S211. The selected feed antenna is offset in a transverse direction from a reference line connecting the focal point of the curved reflector and a reference position on the transverse axis of the AUT positioner, where the reference line is perpendicular to the transverse axis. The selected feed antenna is also offset in an azimuth direction from a reference angle corresponding the AUT being positioned on the transverse axis at the reference line connecting the focal point of the curved reflector and the reference position of the AUT positioner, where the reference angle provides a planar phase front of the AUT parallel to a reference focal plane RFP at the focal point. Accordingly, an offset focal plane corresponding to the selected feed antenna is angularly offset (tilted) from the reference focal plane RFP, which is perpendicular to the reference line at the transverse axis of the AUT positioner, as discussed below. The feed antenna may be selected automatically by the controller based on a test plan, and/or based on frequencies of the RF signals being tested and corresponding frequencies of the feed antennas. Alternatively, or in addition, the feed antenna may be manually selected by the user via a user IF to the controller, for example.

In block S212, an offset angle φ is determined in relation to the selected feed antenna as the angle of rotation of the AUT around an azimuth axis that aligns the AUT with the offset focal plane coming in from the offset selected feed antenna when the AUT is positioned at an offset location (discussed below), such that a planar phase front of the AUT is parallel to the offset focal plane. The offset angle φ is determined by determining the angle between the offset focal plane associated with the selected feed antenna and the reference focal plane RFP that is perpendicular to the reference line, which is equal to the offset angle φ. The offset focal plane is perpendicular to a line corresponding to the main (center) beam of an RF signal transmitted or received by the selected feed antenna. The offset angle φ is determined as a function of phase front distance and transverse distance according to Equation (2), where the transverse distance is the hypotenuse of a right triangle in which the phase front distance is the opposite side of the offset angle φ and a line that is parallel to the offset focal plane and connects the hypotenuse and the opposite side is the adjacent side of the tilt angle φ.

In block S213, a transverse offset t_{off} is determined as the distance between the reference position of the AUT on the transverse axis and the desired offset location (offset location) of the AUT on the transverse axis, where the offset location places the AUT in a center of a quiet zone. The center of the quiet zone is where phase and amplitude variations of the RF signals are minimized, which best supports reception and transmission of the RF signals. The transverse offset t_{off} is determined as a function of the offset angle φ and reflector distance according to Equation (3), where the reflector distance is the length of the reference line between the focal point of the curved reflector and the reference position on the transverse axis of the AUT positioner. As mentioned above, the reference line forms a right angle with the transverse axis, and thus the transverse offset t_{off} as well. Accordingly, the offset angle φ is formed between the reference line and the center line of the main beam of the RF signal communicated between the selected feed antenna and the offset location of the AUT on the transverse axis. Therefore, with regard to the offset angle φ, the center line of the main beam is the hypotenuse of a right triangle, the reference line is the adjacent side of the right triangle, and the transverse offset t_{off} to be determined is the opposite side of the right triangle.

In an embodiment, determination of the offset angle φ in block S212, and determination of the transverse offset t_{off} in block S213 may be performed by the controller making real time or near real time calculations. In alternative embodiments, one or both of the offset angle φ and the transverse offset t_{off} may be determined using a look-up table or other relational database.

In block S214, the AUT is positioned along the transverse axis of the AUT positioner in accordance with the determined transverse offset t_{off}, and is positioned rotationally around the azimuth axis in accordance with the determined offset angle φ. In particular, the AUT is moved linearly along the transverse axis of the AUT positioner a distance equal to the determined transverse offset t_{off} from the reference position to the offset location, and is rotated around the azimuth axis by an angle equal to the offset angle φ. The AUT may be moved automatically by the controller sending control signals to linear and rotational actuators, which move a moveable platform to which the AUT is mounted the transverse offset t_{off} distance and the offset angle φ, respectively. Alternatively, the AUT may be moved manually by the user in the linear and/or angular directions, by hand or by interfacing with the controller at the user IF, in response to the controller displaying information identifying the offset location on the transverse axis and the offset angle in relation to the azimuth axis. It is understood that the transverse and azimuthal positioning of the AUT positioner may be done in any order, or simultaneously, in regard to one another and in regard to the determination steps, without departing from the scope of the present teachings.

In block S215, measurements of at least one far-field characteristic of the AUT are made using the selected offset feed antenna with the AUT positioned by the AUT positioner in in accordance with the determined offset angle φ and the determined transverse offset t_{off}. The measurements may be made using a signal processor that sends and receives RF signal data through a transceiver.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those having ordinary skill in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to an advantage.

Aspects of the present invention may be embodied as an apparatus, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit” or “system.” Furthermore, aspects of the present invention may take the form of a computer program product embodied in one or more computer readable medium(s) having computer executable code embodied thereon.

The various components, structures, characteristics and methods are included by way of illustration and example only and not in any limiting sense. In view of this disclosure, those skilled in the art can implement the present teachings in determining their own applications and needed components, materials, structures and equipment to implement these applications, while remaining within the scope of the appended claims.

While representative embodiments are disclosed herein, one having ordinary skill in the art appreciates that many variations that are in accordance with the present teachings are possible and remain within the scope of the appended claim set. The invention therefore is not to be restricted except within the scope of the appended claims.

What is claimed:

1. A system for measuring at least one far-field characteristic of an antenna under test (AUT), the system comprising:
an AUT positioner configured to position the AUT on a transverse axis of the AUT positioner and an azimuth axis of the AUT;
a curved reflector defining a reference focal plane corresponding to a focal point of the curved reflector at a reference position on the transverse axis of the AUT positioner;
a measurement array comprising a plurality of feed antennas configured to send radio frequency (RF) signals to the AUT and/or receive RF signals from the AUT reflected by the curved reflector, wherein a selected feed antenna of the plurality of feed antennas is offset from a reference line connecting the focal point of the curved reflector and the reference position on the transverse axis of the AUT positioner, such that an offset focal plane corresponding to the selected feed antenna is angularly offset from the reference focal plane by an offset angle; and
a controller programmed to determine the offset angle and a transverse offset from the reference position to an offset location on the transverse axis of the AUT positioner,
wherein the AUT positioner positions the AUT at the offset angle and the offset location for receiving RF signals from the selected feed antenna and/or transmitting RF signals to the selected feed antenna, wherein when positioned at the offset angle and the offset location, the AUT has a planar phase front parallel to the offset focal plane of the selected feed antenna and is in a center of a quiet zone of the selected feed antenna.

2. The system of claim 1, wherein the controller is further programmed to control the AUT positioner to move the AUT to the offset angle and the offset location.

3. The system of claim 1, wherein the controller is programmed to determine the offset angle by:
estimating a transverse distance (TD) of a movement of the AUT along the transverse axis of the AUT positioner;
determining a phase front distance (PFD) based on phase of the RF signal measured at a beginning of the movement and phase measured at an end of the movement of the AUT over the transverse distance (TD) along the transverse axis of the AUT positioner, multiplied by a wavelength of the RF signal and divided by 360; and
calculating the offset angle based on the transverse distance (TD) and the phase front distance (PFD).

4. The system of claim 3, wherein the offset angle (φ) of the AUT is calculated based on based the transverse distance (TD) and the phase front distance (PFD) as follows:
$$φ = arcsin ( \frac{PFD}{TD} ) .$$

5. The system of claim 1, wherein the transverse offset is calculated based on the offset angle and a reflector distance which is equal to a length of the reference line connecting the focal point of the curved reflector and the reference position on the transverse axis of the AUT positioner.

6. The system of claim 5, wherein the transverse offset (t_{off}) is calculated as follows:
$${t}_{offset} = tan ( φ ) * reflector distance .$$

7. The system of claim 1, further comprising:
a memory configured to store offset locations corresponding to the plurality of feed antennas, respectively; and
a controller programmed to retrieve the offset location for the AUT corresponding to the selected feed antenna, and to control the AUT positioner to move the AUT to the retrieved offset location.

8. The system of claim 1, wherein the plurality of feed antennas have different frequency ranges, respectively, and
wherein the selected feed antenna is selected based on the respective frequency range corresponding to an in-band frequency range of the AUT.

9. The system of claim 1, further comprising:
an anechoic chamber housing the AUT, the curved reflector and the measurement array.

10. The system of claim 1, wherein the reference line connecting the focal point of the curved reflector and the reference position on the transverse axis of the AUT positioner is at a zero degree angle from a center of the curved reflector.

11. The system of claim 1, further comprising:
a transceiver configured to transmit the RF signals to the AUT and/or to receive RF signals from the AUT via the selected feed antenna; and
a switch operable by the controller to selectively connect the selected feed antenna to the transceiver.

12. A method for measuring at least one far-field characteristic of an antenna under test (AUT) on an AUT positioner in a compact anechoic test range (CATR), the CATR including a plurality of feed antennas and a curved reflector defining a reference focal plane corresponding to a focal point of the curved reflector at a reference position on a transverse axis of the AUT positioner, the method comprising:
selecting an offset feed antenna of the plurality of feed antennas for receiving a radio frequency (RF) signal, wherein the offset feed antenna is offset from a reference line connecting the focal point of the curved reflector and the reference position on the transverse axis of the AUT positioner, such that an offset focal plane corresponding to the selected feed antenna is angularly offset from the reference focal plane;
calculating an offset angle φ of the AUT in relation to the selected offset feed antenna, wherein a planar phase front of the AUT is parallel to the offset focal plane of the offset feed antenna at the offset angle φ;
calculating a transverse offset t_{off} between the reference position of AUT and an offset location of AUT on the transverse axis;
positioning the AUT on transverse axis in accordance with offset angle φ and transverse offset t_{off}, such that the AUT has a planar phase front parallel to the offset focal plane of the selected feed antenna and is in a center of a quiet zone of the selected feed antenna; and
measuring the at least one far-field characteristic of AUT using selected offset feed antenna.

13. The method of claim 12, wherein calculating the offset angle φ comprises:
estimating a transverse distance (TD) of a movement of the AUT along the transverse axis of the AUT positioner;
determining a phase front distance (PFD) based on phase of the RF signal measured at a beginning of the movement and phase measured at an end of the movement of the AUT over the transverse distance (TD) along the transverse axis of the AUT positioner, multiplied by a wavelength of the RF signal and divided by 360; and
calculating the offset angle φ based on the transverse distance (TD) and the phase front distance (PFD).

14. The method of claim 13, wherein the offset angle φ of the AUT is calculated based on based the transverse distance (TD) and the phase front distance (PFD) as follows:
$$φ = arcsin ( \frac{PFD}{TD} ) .$$

15. The method of claim 13, wherein the transverse offset t_{off} is calculated based on the offset angle φ and a reflector distance which is equal to a length of the reference line connecting the focal point of the curved reflector and the reference position on the transverse axis of the AUT positioner.

16. The method of claim 15, wherein the transverse offset t_{off} is calculated as follows:
$${t}_{offset} = tan ( φ ) * reflector distance .$$

17. The method of claim 12, wherein the plurality of feed antennas have different frequency ranges, respectively, and
wherein the selected feed antenna is selected based on the respective frequency range corresponding to an in-band frequency range of the AUT.

18. A system for measuring at least one far-field characteristic of an antenna under test (AUT), the system comprising:
an AUT positioner configured to move the AUT on a transverse axis of the AUT positioner and to rotate the AUT on an azimuth axis of the AUT;
a curved reflector defining a reference focal plane corresponding to a focal point of the curved reflector at a reference position on the transverse axis of the AUT positioner;
a feed antenna configured to communicate a radio frequency (RF) signal with the AUT, wherein the RF signal is reflected by the curved reflector, and wherein the feed antenna is offset from a reference line connecting the focal point of the curved reflector and the reference position on the transverse axis of the AUT positioner, such that an offset focal plane corresponding to the selected feed antenna is angularly offset from the reference focal plane by an offset angle; and
a controller comprising one or more processing units and non-transitory memory storing instructions that, when executed by the one or more processing units, cause the one or more processing units to:
calculate the offset angle;
calculate a transverse offset from the reference position to an offset location on the transverse axis of the AUT positioner based on the offset angle; and
control the AUT positioner to move the AUT to the offset angle and the offset location for communicating the RF signal with the AUT, wherein when positioned at the offset angle and the offset location, the AUT has a planar phase front parallel to the offset focal plane of the selected feed antenna and is in a center of a quiet zone of the selected feed antenna.

19. The system of claim 18, wherein the instructions cause the one or more processing units to calculate the offset angle by:
estimating a transverse distance (TD) of a movement of the AUT along the transverse axis of the AUT positioner;
determining a phase front distance (PFD) based on phase of the RF signal measured at a beginning of the movement and phase measured at an end of the movement of the AUT over the transverse distance (TD) along the transverse axis of the AUT positioner, multiplied by a wavelength of the RF signal and divided by 360; and
calculating the offset angle φ based on the transverse distance (TD) and the phase front distance (PFD).

20. The system of claim 19, wherein the instructions cause the one or more processing units to calculate the transverse offset based on the offset angle φ and a reflector distance which is equal to a length of the reference line connecting the focal point of the curved reflector and the reference position on the transverse axis of the AUT positioner.
